(19) United States
(12) Patent Application Publication
(10) Pub. No.: US 2021/0265515 A1
(43) Pub. Date: Aug. 26, 2021

(54) A MULTILAYER PHOTOVOLTAIC PANEL WITH INCREASED SOLAR RADIATION ENERGY TO ELECTRIC ENERGY CONVERSION SURFACE

(71) Applicant: Janusz Chuptys Contissi, Debica (PL)

(72) Inventor: Piotr CHUPTYS, Debica (PL)

(73) Assignee: Janusz Chuptys Contissi, Debica (PL)

(21) Appl. No.: 17/253,416

(22) PCT Filed: Jun. 21, 2019
(86) PCT No.: PCT/PL2019/000045

§ 371 Date: Dec. 17, 2020

(30) Foreign Application Priority Data
Jun. 20, 2018 (PL) P.425998
Jun. 7, 2019 (PL) P.430186

(51) Int. Cl. H01L 31/043; H02S 40/42; H02S 40/20; H02S 30/10; H01L 31/0445

(52) U.S. Cl. CPC H01L 31/043; H02S 40/425; H01L 31/0445; H02S 30/10; H02S 40/20

(57) ABSTRACT

The subject of the invention is a multilayer photovoltaic panel with increased solar radiation energy to electric energy conversion surface which is characterised in that it comprises a lattice subassembly (1, 16, 23, 34, or 39) or at least one the chamber subassembly (44, 49, 54′, or 60′), in which the component photovoltaic modules (6 and 7) or (18 and 20) or (24 and 30) or (35) or (40) or (45) or (50) or (54) or (60) are connected inseparably with a photovoltaic layer (3) or (11) of the perforated support plate (2) or (17), whereas the perforated support plate (2) constitutes a plate-shaped stiffening element (14) with a single photovoltaic layer (3) or the perforated support plate (17) constitutes a plate-shaped stiffening element (14) both of the two surfaces of which are provided with photovoltaic layers (11).

### CROSS REFERENCE TO RELATED APPLICATION

This application is a national stage entry of PCT/PL2019/000045 filed Jun. 21, 2019, under the International Convention claiming priority over Poland Patent Application No. P.425998 filed Jun. 20, 2018 and Poland Patent Application No. P.430186 filed Jun. 7, 2019.

### FIELD OF THE INVENTION

The subject of the invention is a multilayer photovoltaic panel with increased solar radiation energy to electric energy conversion surface.

### BACKGROUND OF THE PRIOR ART

Photovoltaic (PV) conversion is the most perfect method of converting solar energy into electric energy as it is a direct conversion process.

Perovskites are crystalline minerals replacing silicon used to date in production of photovoltaic cells and modules. Photovoltaic cells made of perovskite are much lighter and thinner than the most popular silicon cells and what is more, more elastic as far as the engineering design process is concerned.

A photovoltaic cell is a basic element of any photovoltaic system. A single cell generates current with power of 2-4 W, and to obtain higher voltages nor current intensities, cells are connected in series or in parallel to form a photovoltaic module. Further, photovoltaic systems are composed of a plurality of photovoltaic modules which are interconnected to obtain higher output power. The systems generate direct current.

The current intensity level at panel output depends strictly on sun exposure, but can be increased by connecting modules in parallel. The voltage obtained from a module depends on sun exposure only to a small degree. Photovoltaic systems can be designed for operation at virtually any voltage up to several hundred volts by connecting modules in series. In small applications, photovoltaic panels may operate only at voltage of 12 or 24 volts, whereas in applications connected to power supply grids, large panels can be operated at 240 volts or more. Photovoltaic modules are composed of a plurality of photovoltaic cells connected with each other which convert sunlight energy into electric energy. In known systems, the cells are disposed between a glass pane and suitable laminating films protecting the cells against mechanical, physical, and chemical factors contributing to degradation of the cells. The whole electrical circuit of connected cells making up the module is provided with terminal leads and suitable output sockets provided on the back side of the module.

From description of Polish patent No. PL225540 known is a multilayer dye-sensitised photovoltaic cell comprising a photoelectrode and electrodes characterised in that the photoelectrode is provided with a “n”-type coating sensitised by means of a dye with a conjugated donor-acceptor form with doubled anchoring group, on which in turn a layer of a material transporting holes is deposited, said material being the nickel or titanium phthalocyanine and said layer provided with electrodes on its top. The solution allows to increase efficiency of the cell thanks to motion of electrons being forced by the use of organic dyes with conjugated form of the donor-anchoring acceptor structure.

From European patent description No. EP3163629 known is also a semi-elastic photovoltaic module comprising a set of photovoltaic cells, including perovskite cells or dye-sensitised cells DSSC, situated between two EVA film encapsulants of which one is covered with a strengthened glass pane and the other with an electrically insulating film, provided with connectors and a connecting cable, whereas all the elements are hermetically laminated.

From European patent application No. EP3136450 known is also a perovskite solar cell comprising two outer electrode layers between which the following layers are disposed: a recombination preventing layer, a photoactive layer, and a defect electron transporting layer, whereas the photoactive layer includes a double layer of perovskite.

### SUMMARY OF THE INVENTION

The objective of the present invention is to provide a structure of a photovoltaic panel utilising photovoltaic layers, especially perovskite cells, characterised with increased efficiency of conversion of scattered solar energy and high reliability of operation by maximising the area of surfaces on which photoelectric conversion takes place. Another objective of the invention is to increase versatility of the prior art solutions because it has been found that at continuous sun exposure and high temperatures, both the lattice subassemblies and the chamber subassemblies of the panel are subject to overheating which results in deterioration of effectiveness of conversion of solar energy to electric power. A further objective of the invention is to provide such a structure for a photovoltaic panel which will offer the possibility to produce such air draught induced by at least one rotating propeller mounted to the support plate of the photovoltaic panel which will ensure not only the desired cooling action for lattice subassembly or chamber subassembly of the panel, but also, when and where necessary, will induce also a lift force capable to rise the whole assembly upwards and manoeuvre it in the air, whereas embodiments of these improvements will include a control system based on wireless communication with the use of a remote control equipped with a program to communicate with a PC-type computer.

The multilayer photovoltaic panel with increased solar radiation energy to electric energy conversion surface, in which the modules converting the energy are constructed based on photovoltaic modules according to the invention is characterised in that it has a lattice subassembly or at least one chamber subassembly, where the component photovoltaic modules are connected inseparably with a photovoltaic layer or with photovoltaic layers of a perforated support plate.

The perforated support plate constitutes preferably a plate-shaped stiffening element with one photovoltaic layer or with two photovoltaic layers.

Also favourably:
the lattice subassembly of the panel is composed of rectangular strip-shaped bearing photovoltaic modules and of analogous flat transverse photovoltaic modules, composed of plate-shaped stiffening elements both of the two outer surfaces of which are provided with photovoltaic layers, whereas both of the two types of photovoltaic modules are arranged perpendicularly relative to each other and connected with each other by means of the push-on method by means of slit-shaped recesses made on their longer upper sides so that both lower and upper surfaces of these strip-shaped photovoltaic modules are flush with one another, while widths of the slit-shaped recesses in the modules are adapted to thickness of these strip-shaped modules, or
the lattice subassembly of the panel is composed of strip-shaped bearing flat photovoltaic modules and arranged parallel relative to each other with their longer upper sides provided with slit-shaped recesses oriented at an acute angle respective to their uppers surfaces and of strip-shaped transverse photovoltaic modules with slit-shaped recesses arranged perpendicularly on their longer sides, whereas both of the two photovoltaic modules are composed of plate-shaped stiffening elements both of the two outer surfaces of which are provided with photovoltaic layers, and further, the modules are connected with each other by means of the push-on method with the use of slit-shaped recesses so that upper ends of the photovoltaic modules stick out above upper surfaces of the photovoltaic modules; or
the lattice subassembly of the panel is composed of flat strip-shaped bearing photovoltaic modules arranged parallel relative to each other and provided, on their longer sides, with evenly distributed pairs of slit-shaped recesses oriented at an acute angle respective to their upper surfaces, and of strip-shaped transverse photovoltaic modules, also arranged parallel relative to each other, provided with slit-shaped recesses are arranged perpendicularly relative to their longer sides, whereas the photovoltaic modules of both of these two types are composed of plate-shaped stiffening elements both of the two outer surfaces of which are provided with photovoltaic layers, and moreover, the modules are connected with each other by means of the push-on method so that upper ends of the transverse photovoltaic modules are oriented obliquely relative to each other and stick out above surfaces of upper sides of the photovoltaic modules; or
the lattice subassembly of the panel are constructed as circular tubular photovoltaic modules arranged vertically in rows side by side so that first modules of each second row are advanced by a half of their diameters, with all the modules being connected with each other at their contact points by means of an electrically conductive adhesive, forming thus a monolithic subassembly, whereas all the tubular photovoltaic modules have the form of tubular stiffening elements both of the two outer surfaces of which are provided with photovoltaic layers; or
the lattice subassembly of the panel comprises photovoltaic modules with the profile of triangular tubes arranged vertically and their side walls connected with each other by means of layers of an electrically conductive adhesive, said modules having the form of stiffening elements both of the two outer surfaces of which are provided with photovoltaic layers.

It is also favourable when lower face walls of rectangular flat plate-shaped photovoltaic modules, constituting elements of the lattice subassembly of the panel, are permanently connected to upper face surfaces of the tubular circular photovoltaic modules by means of layers of electrically conductive adhesive

It is further favourable when:
the chamber subassembly of the panel is composed of circular tubular photovoltaic modules with different diameters and identical height, arranged concentrically relative to each other, each of the modules having the form of a tubular stiffening element both of the two outer surfaces of which are provided with photovoltaic layers, whereas cylindrical chambers are formed between the modules; or
the chamber subassembly of the panel is composed of triangular tubular photovoltaic modules with identical heights, separated from each other with triangular chambers, each of the modules having the form of a plate-shaped stiffening elements both of the two outer surfaces of which are provided with photovoltaic layers; or
the chamber subassembly of the panel constitutes an inner stiffening element both of the two outer surfaces of which are provided with photovoltaic layers, said element having the profile of a triangular scroll of triangles situated concentrically respective to each other, said profile having an open inner and an open outer end, whereas a continuous chamber is formed inside said triangular profile; or
the chamber subassembly of the panel has the form of an inner stiffening element with the profiled of a circular scroll both of the two outer surfaces of which are provided with photovoltaic layers with a continuous chamber formed between coils of the scroll.

It is further favourable when the stiffening elements of the panel are made of polyethylene terephthalate (PET) or of isolated graphene.

It is also favourable when photovoltaic layers of the modules of the panel are perovskite layers or DSSC cells or QD cells or OPV cells.

Favourable are also such improvements of these multilayer photovoltaic panels the subject-matter of which consists in that:
in a first improved version, an electric motor is mounted in vertical axis of symmetry of support plates with one or two perovskite photovoltaic layers of lattice subassemblies or chamber subassemblies joined inseparably with and in profiled coaxial sockets formed said subassemblies, or in a coaxial inner cylindrical photovoltaic module, or in a coaxial inner triangular chamber, or in a coaxial hole of the scroll-shaped chamber subassembly, said motor being joined detachably with said sockets, or with said cylindrical photovoltaic module, or with the coaxial inner triangular chamber, or with the axial hole of the scroll-shaped chamber subassembly and with these perforated support plates, so that the drive shaft of the motor is mounted with some clearance in axial hole of respective support plate, and lower end of the shaft is provided with a propeller set in rotary motion by the motor, whereas the whole structure of each of the multilayer photovoltaic panel is placed in a cylindrical tube joined detachably with respective lattice subassembly or chamber subassembly so that a circumferential slit is formed between outer surface of the cylindrical tube and side walls of respective subassembly;
support plates are equipped with several electric motors, fixed to said plates, distributed symmetrically with respect to said plates and to each other, and provided with propellers;
on the other hand, in the second improvement version, lower end of a drive shaft of an electric motor is mounted to respective support plate in their symmetry axes and to lattice subassemblies or chamber subassemblies joined inseparably to said support plates, said shaft end setting in rotary motion a subassembly composed of the corresponding support plate and the corresponding lattice subassembly or chamber subassembly, whereas the motor, by means of several supporting bar-shaped elements situated horizontally and symmetrically with respect to each other, is joined with lower end of a cylindrical tube so that the lower portion of the panel is fixed in upper portion of the cylindrical forming thus a circumferential slit between the inner surface of the tube and side walls of respective support plate.

The use of photovoltaic modules in the form of subassemblies with lattice-shaped profiles and mutually concentric arrangement of profiled photovoltaic modules with double-sided photovoltaic layers and chambers formed between the modules, connected electrically with a perforated support plate also provided with a photovoltaic layer or layers allows to increase the surface area on which photoelectric conversion takes place thanks to the use of photovoltaic cells characterised with increased efficiency of conversion of scattered solar energy. Moreover, the structure of the photovoltaic panel according to the invention allows to concentrate locally the absorption of energy coming from objects (for instance hail) impacting the panel minimising thus possible damage to the panel which is a direct consequence of the structure of its face. Additionally it has been found that such structure of the panel enables free flow of air between individual modules and through openings of perforation in the base improving thus effective cooling of the module. On the other hand, equipping the lower portion of the multilayer photovoltaic panel additionally with a cylindrical tube with a propeller driven by an electric motor mounted in said tube and in an axial hole of the panel assembly and resting on the support plate of the assembly, and joining it with both said plate and inner surface of the axial hole, resulted in appearance of the desired phenomenon, the so-called called stack effect, ensuring existence of an additional draught enhancing effectiveness of cooling action for the lattice subassembly or the chamber subassembly of the panel.

Further, abandoning the action of cooling these subassemblies of the multilayer photovoltaic panel by means of a propeller and setting the whole assembly of the panel in rotary motion by means of an electric motor mounted in a supporting structure, joined also with lower portion of a cylindrical tube in upper portion of which placed is only lower portion of the multilayer photovoltaic panel together with its support plate, also resulted in appearance of the stack effect and obtaining the desired phenomenon of cooling the lattice subassembly or the chamber subassembly of the photovoltaic panel. Moreover, it has been unexpectedly found that such integration of the support plate of the multilayer photovoltaic panel assembly with at least one electric motor equipped with propeller and placing the lower portion of the panel assembly inside the upper portion of the cylindrical tube resulted in appearance of such lift force which made it obvious that there is a possibility to lift the assembly vertically upwards and manoeuvre it in the air by using for this purpose a remote wireless communication system comprising a remote control device equipped with a computer program and a class PC computer.

### BRIEF DESCRIPTION OF THE DRAWINGS

FIG. 1 shows a perpective front view of the panel according to an embodiment of the present invention;

FIG. 2 shows an exploded front view of the components of the panel of FIG. 1;

FIG. 3 shows a front view of one of the strip-shaped bearing or transverse photovoltaic modules with double-sided photovoltaic layers hat is one of the components of the panel of FIG. 1;

FIG. 4 shows a cross sectional view of the same bearing or transverse element in enlarged transverse section taken along line A-A of FIG. 3;

FIG. 5 shows a cross sectional view of a perforated support plate of the panel with one-sided photovoltaic layer in enlarged transverse section taken along line B-B on FIG. 1;

FIG. 6 shows a detailed view of the panel of FIG. 1;

FIG. 7 shows a detailed view of the panel of FIG. 1;

FIG. 8 shows a perspective front view of the panel of the present invention according to a second embodiment of the present invention;

FIG. 9 shows an exploded front view of the components of the panel of FIG. 8;

FIG. 10 shows a front view of one of the strip-shaped bearing photovoltaic Imodules with double-sided photovoltaic layers hat is one of the components of the panel of FIG. 8;

FIG. 11 shows a cross sectional view of the same bearing or transverse element in enlarged transverse section taken along line E-E of FIG. 10;

FIG. 12 shows a cross sectional view of a strip shaped bearing and transverce element of the panel taken along line E-E-on FIG. 10;

FIG. 13 shows a cross sectional view of a strip shaped bearing and transverce element of the panel taken along line F-F-on FIG. 11;

FIG. 14 shows a cross sectional view of a perforated support plate with double-sided photovoltaic layer taken along line G-G on FIG. 8;

FIG. 15 shows a detailed view of the panel of FIG. 8;

FIG. 16 a detailed view of the panel of FIG. 8;

FIG. 17 shows a perspective front view of the panel of the present invention according to a third embodiment of the present invention;

FIG. 18 shows an exploded front view of the components of the panel of FIG. 17;

FIG. 19 shows a front view of one of the strip-shaped bearing photovoltaic Imodules with double-sided photovoltaic layers hat is one of the components of the panel of FIG. 17;

FIG. 20 shows a front view of one of the strip-shaped trasnsverse Imodules with double-sided photovoltaic layers hat is one of the components of the panel of FIG. 17;

FIG. 21 shows a cross sectional view of the strip shaped bearing and transverse element in panel taken along line J-J of FIG. 19;

FIG. 22 shows a cross sectional view of a strip shaped and transverce element of the panel taken along line K-K on FIG. 20;

FIG. 23 shows a detailed view of the panel of FIG. 17;

FIG. 24 shows a perspective front view of the panel of the present invention according to a fourth embodiment of the present invention showing a cylindrical lattice structure;

FIG. 25 shows an exploded front view of the components of the panel of FIG. 24;

FIG. 26 shows a perpective front view of the cylindrical photovoltaic modules of the lattice subassembly with double-sided photovoltaic layer of FIG. 24;

FIG. 27 a front view of the cylindrical photovoltaic modules of the lattice of FIG. 26;

FIG. 28 shows a cross sectional view of the cylindrical photovoltaic modules taken along line N-N on FIG. 27;

FIG. 29 shows a detailed view of the cylindrical photovoltaic modules of FIG. 24;

FIG. 30 shows a detailed view of the cylindrical photovoltaic modules of FIG. 24;

FIG. 31 shows a perspective front view of the panel of the present invention according to a fifth embodiment of the present invention showing a with triangular tubular lattice structure;

FIG. 32 shows an exploded front view of the components of the panel of FIG. 31 including the lattice subassembly and perforated support plate disassembled;

FIG. 33 shows front view of the triangular tubular lattice structure of FIG. 31;

FIG. 34 shows a top view of the triangular tubular lattice structure of FIG. 33;

FIG. 35 shows a cross sectional view of the triangular tubular lattice structure taken along line U-U on FIG. 34;

FIG. 36 shows a detailed view of the panel of FIG. 31;

FIG. 37 shows a perspective front view of the panel of the present invention according to a sixth embodiment of the present invention showing a combination of the above-described fourth variant and the oblique lattice structure specific for the second variant of the panel;

FIG. 38 shows an exploded front view of the components of the panel of FIG. 37;

FIG. 39 shows a perspective front view of the panel of the present invention according to a seventh embodiment of the present invention showing four cylindrical tubular photovoltaic modules with different diameters, arranged concentrically respective to each other;

FIG. 40 shows a top view of the four cylindrical tubular photovoltaic modules of FIG. 39;

FIG. 41 shows the same set of photovoltaic modules in axial section taken along line X′-X′ of FIG. 40;

FIG. 42 shows a cross sectional view of one photovoltaic module of the set of modules taken along line X-X of FIG. 40;

FIG. 43 shows a detailed view of the module of FIG. 39;

FIG. 44 shows a perspective front view of the panel of the present invention according to a eight embodiment of the present invention showing four triangular tubular photovoltaic modules with different transverse dimensions of the modules, arranged concentrically respective to each other,

FIG. 45 shows a top view of the four triangular tubular photovoltaic modules of the panel of FIG. 44;

FIG. 46 shows a vertical cross sectional view of one photovoltaic module taken along line B′-B′ of FIG. 44;

FIG. 47 shows a cross sectional view of one photovoltaic module taken along line C′-C′ of FIG. 45;

FIG. 48 shows a detailed view of the module of FIG. 44;

FIG. 49 shows a perspective front view of the panel of the present invention according to a ninth embodiment of the present invention showing photovoltaic modules with the structure of four triangles arranged concentrically respective to each other with their dimensions diminishing towards the centre of the structure disposed on photovoltaic module with the profile of the perforated support plate;

FIG. 50 shows a top view of an isolated photovoltaic module with the structure of a triangular scroll with four coils of FIG. 49;

FIG. 51 shows a vertical cross sectional view of the photovoltaic module with double-sided photovoltaic layers taken along line Z-Z of FIG. 50;

FIG. 52 shows a perspective front view of the panel of the present invention according to a tenth embodiment of the present invention showing a photovoltaic module in the form of a scroll situated on a photovoltaic module with the profile of a perforated support plate;

FIG. 53 shows a top view of the isolated photovoltaic module with the structure of a scroll of FIG. 52;

FIG. 54 shows a vertical cross sectional view of the photovoltaic module with double-sided photovoltaic layers taken along line W-W of FIG. 53;

FIG. 55 shows a perspective front view of the panel of the present invention according to a eleventh embodiment of the present invention showing the first variant of improvement of the first ten variants of the panel, said variant consisting in equipping these earlier variants in an electric motor driving a propeller and further equipping said earlier versions with a cylindrical tube;

FIG. 56 shows a top view of the panel of FIG. 55;

FIG. 57 shows a vertical cross sectional view of the panel taken alone lines W-W of FIG. 56;

FIG. 58 shows a cross sectional view of the panel taken alone lines V-V of FIG. 56;

FIG. 59 shows a perspective front view of the panel of the present invention according to a twelfth embodiment of the present invention showing the same improved multilayer photovoltaic panel equipped additionally only in an electric motor and a cylindrical tube;

FIG. 60 shows a top view of the panel of FIG. 59;

FIG. 61 shows a vertical cross sectional view of the panel taken alone lines V′-V′ of FIG. 60; and

FIG. 62 shows a cross sectional view of the panel taken alone lines V″-V″ of FIG. 60.

### DESCRIPTION OF THE INVENTION

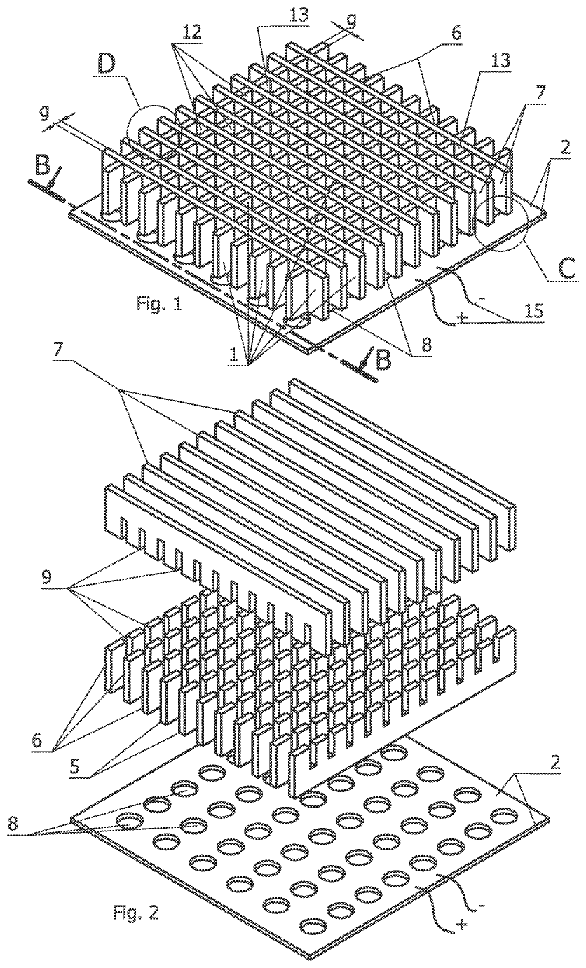

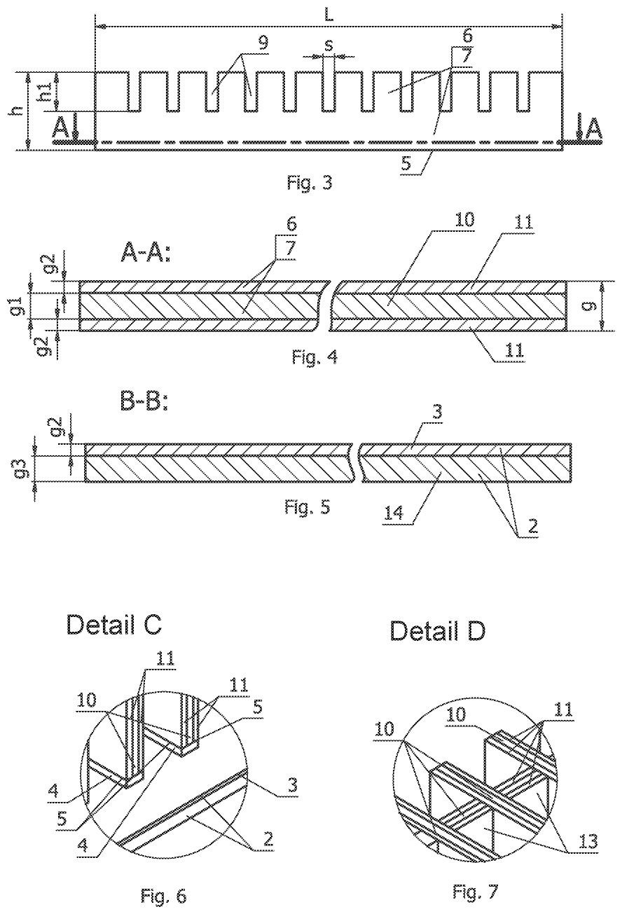

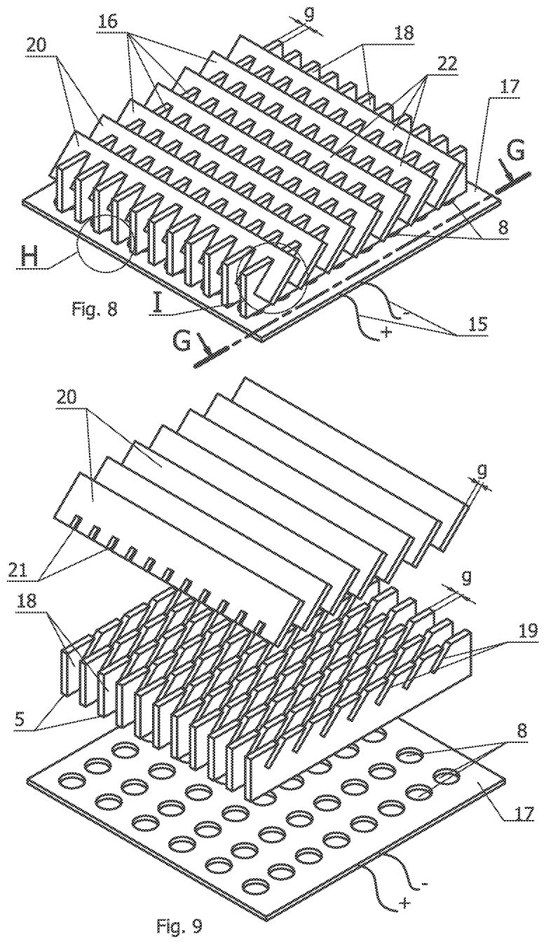

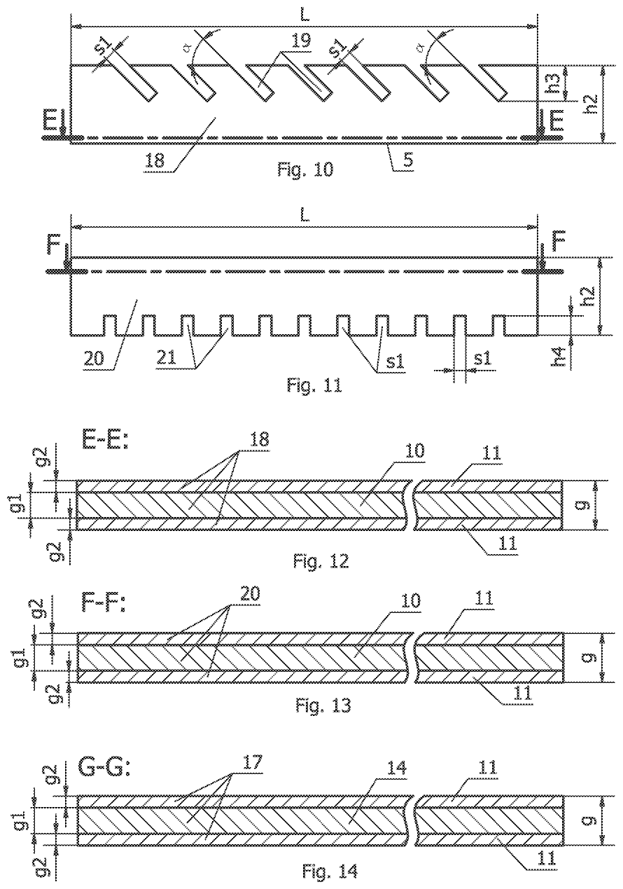

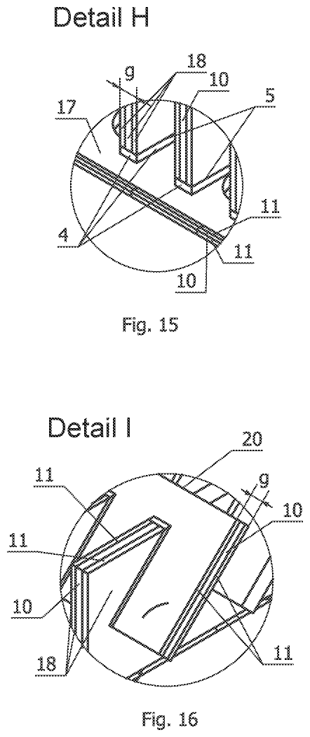

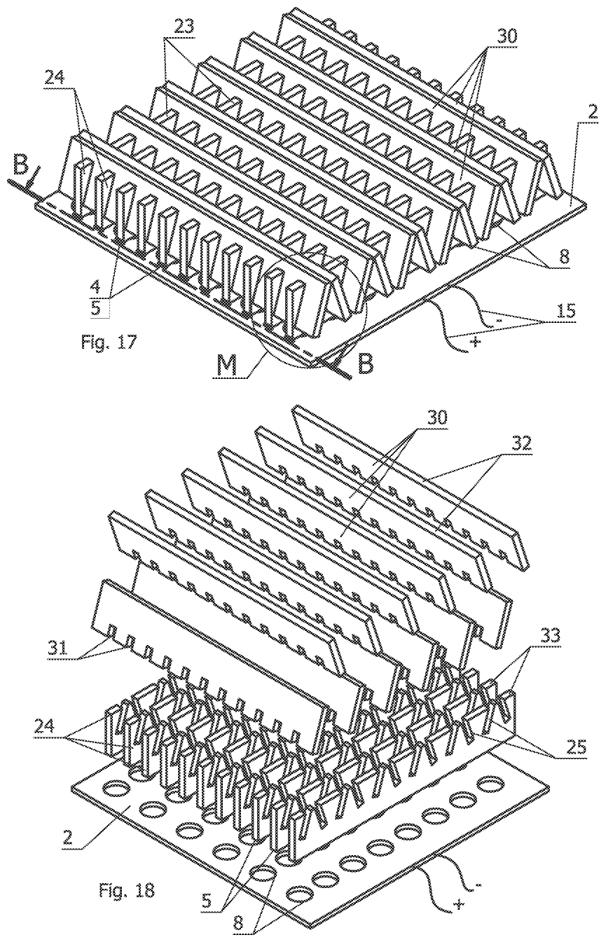

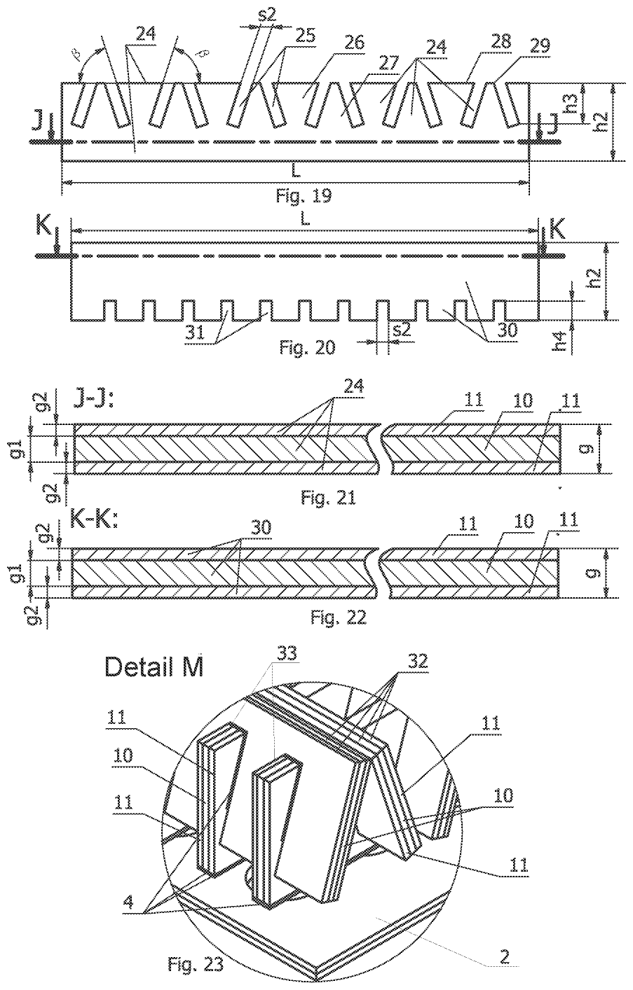

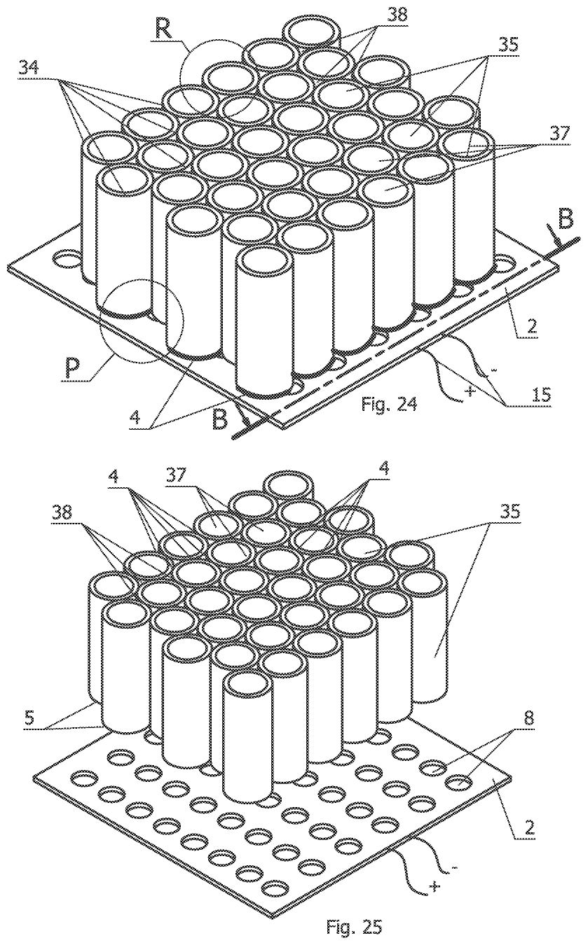

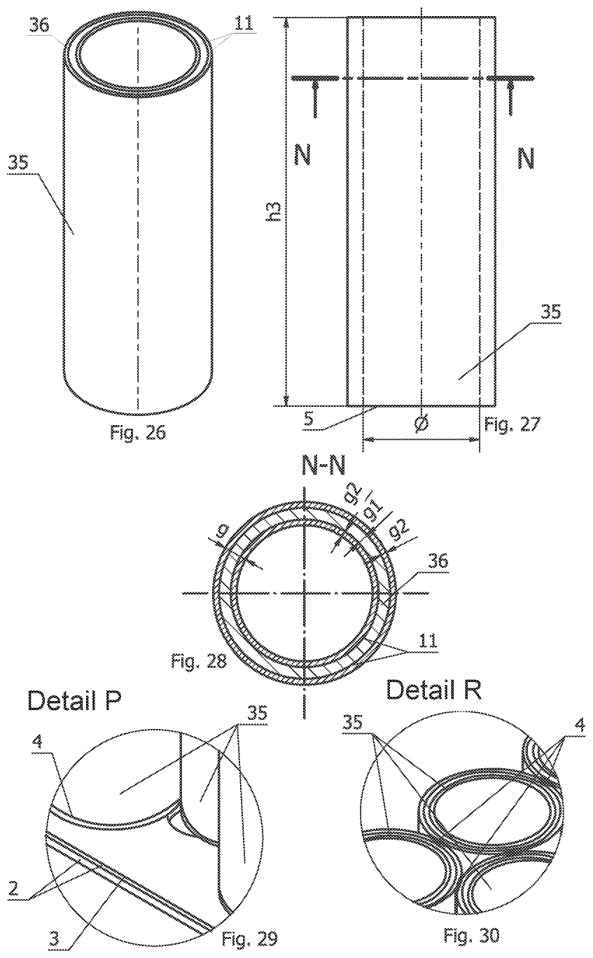

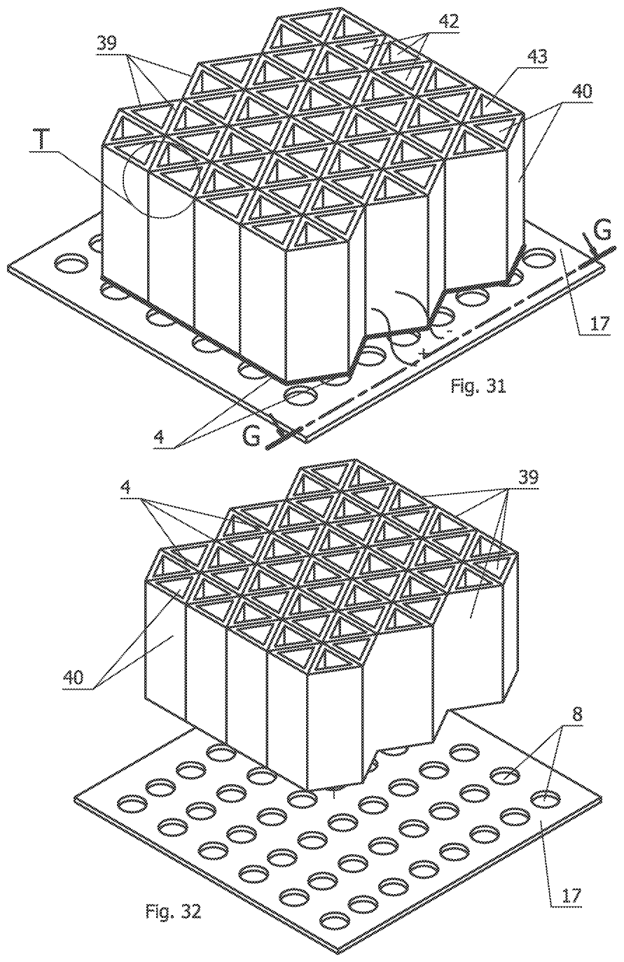

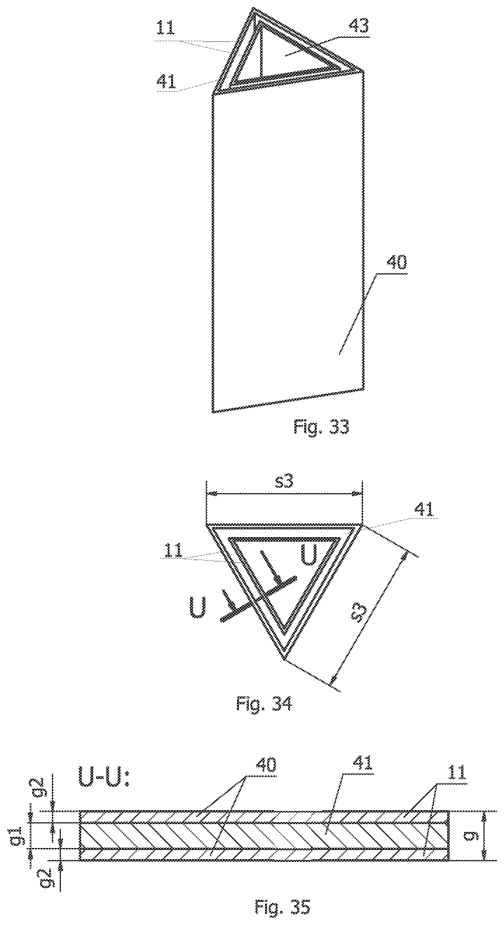

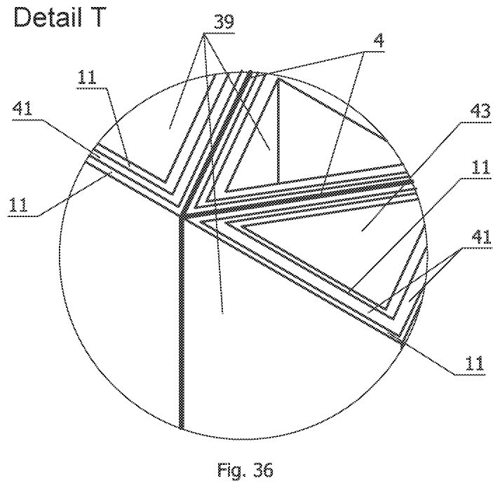

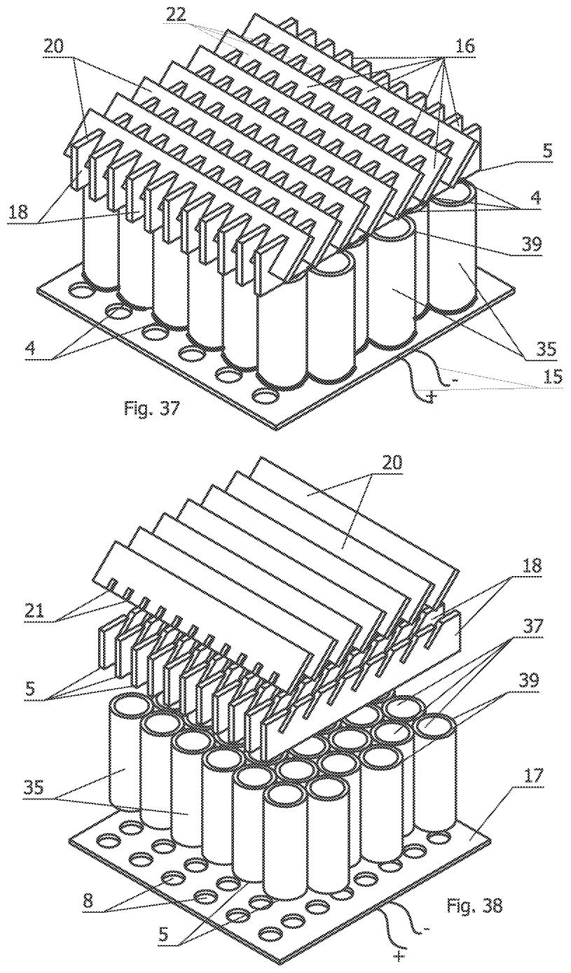

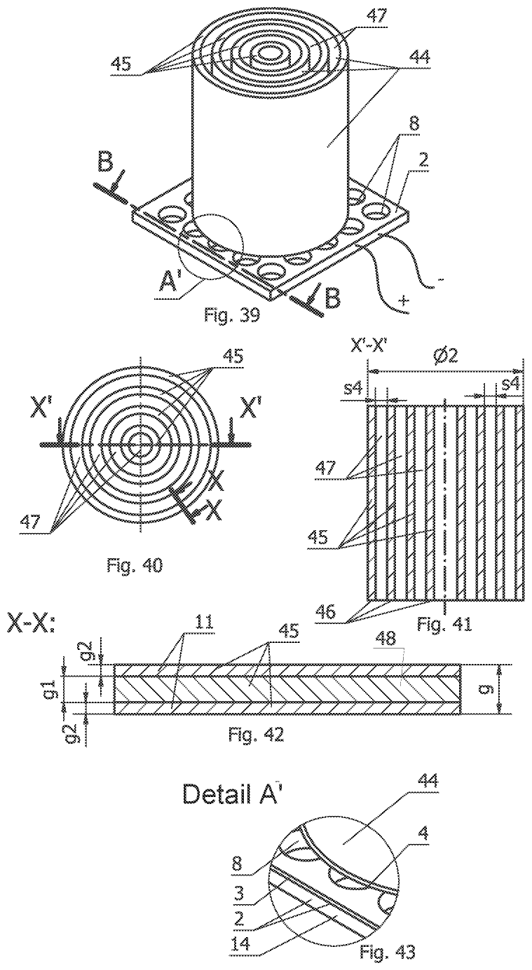

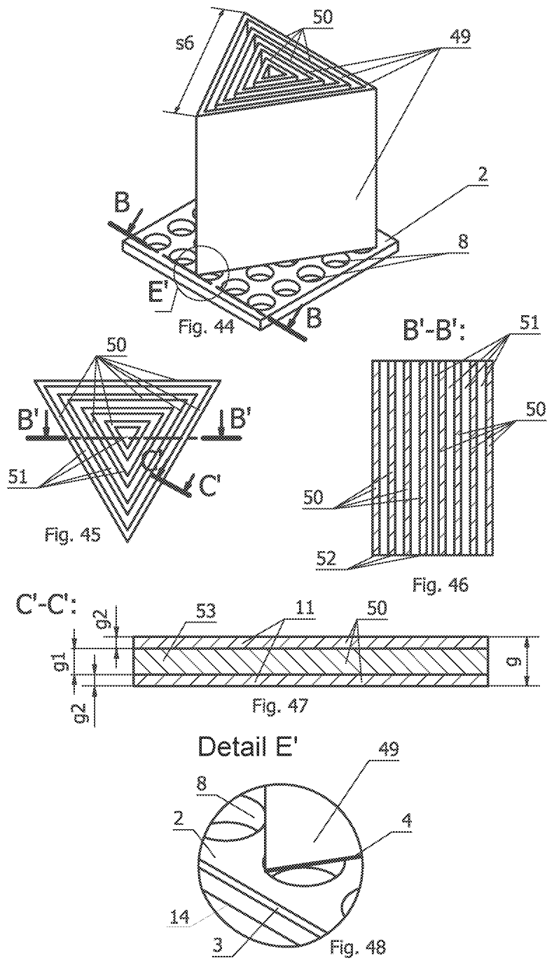

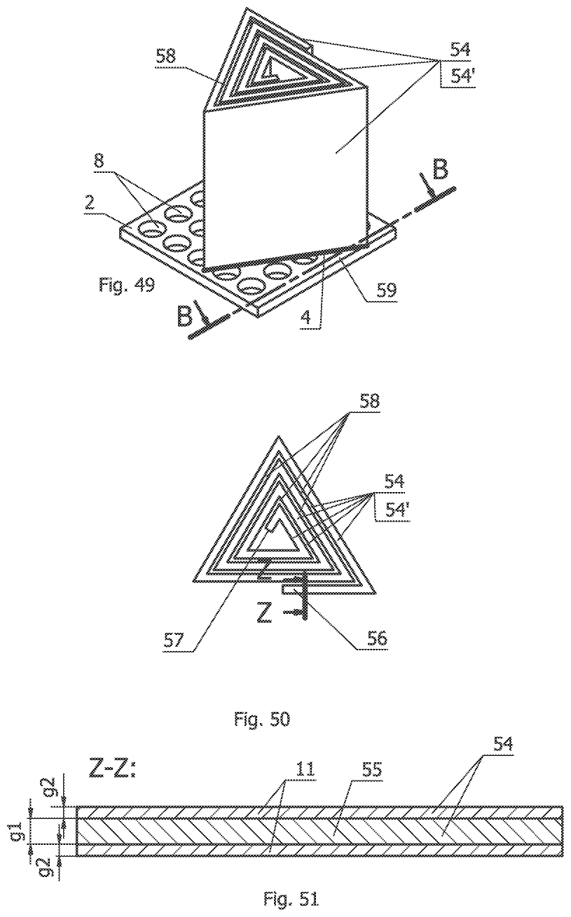

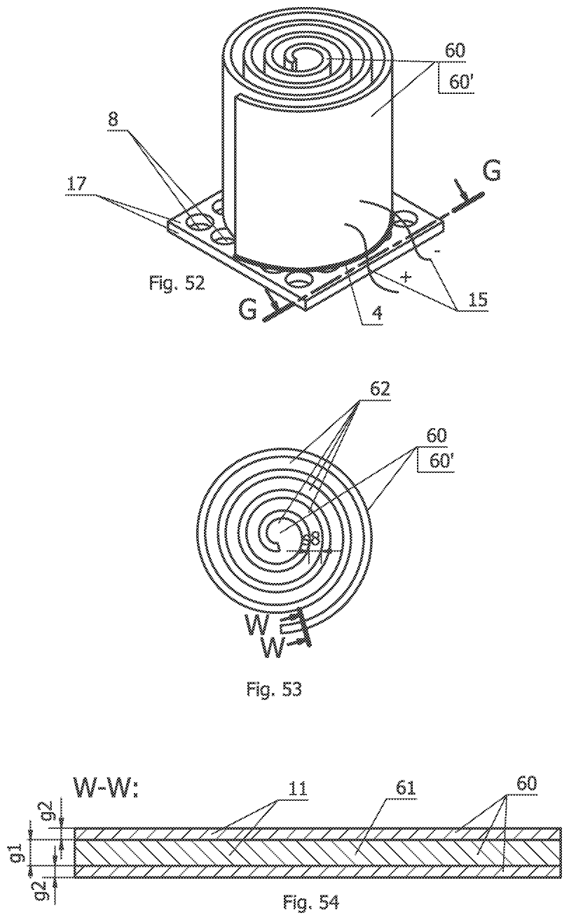

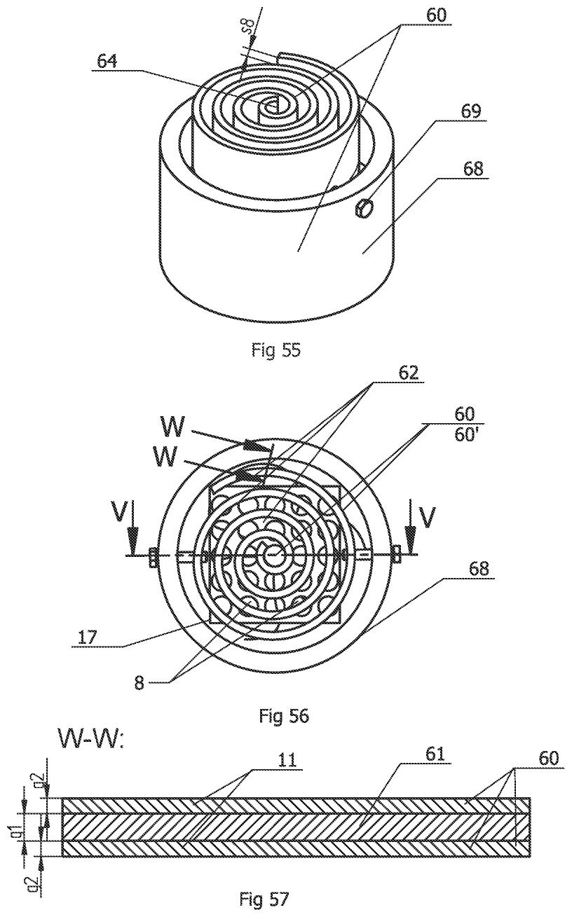

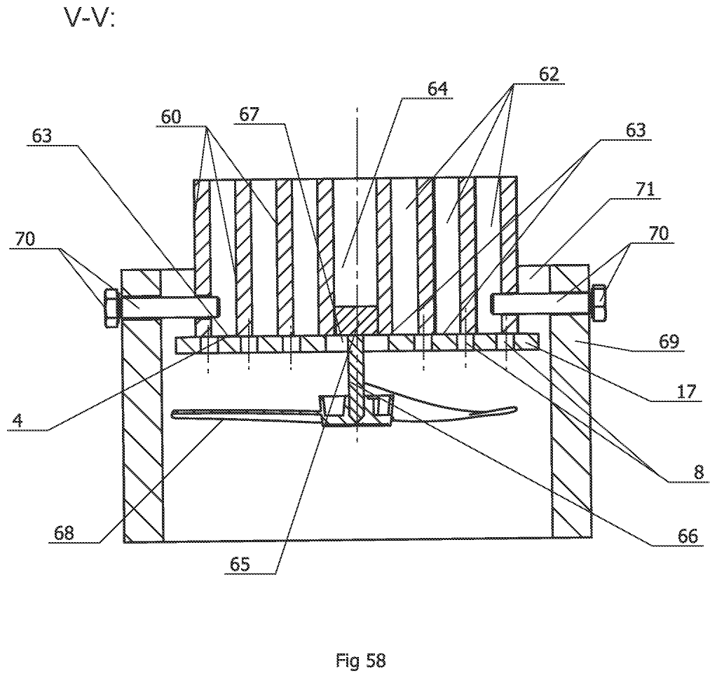

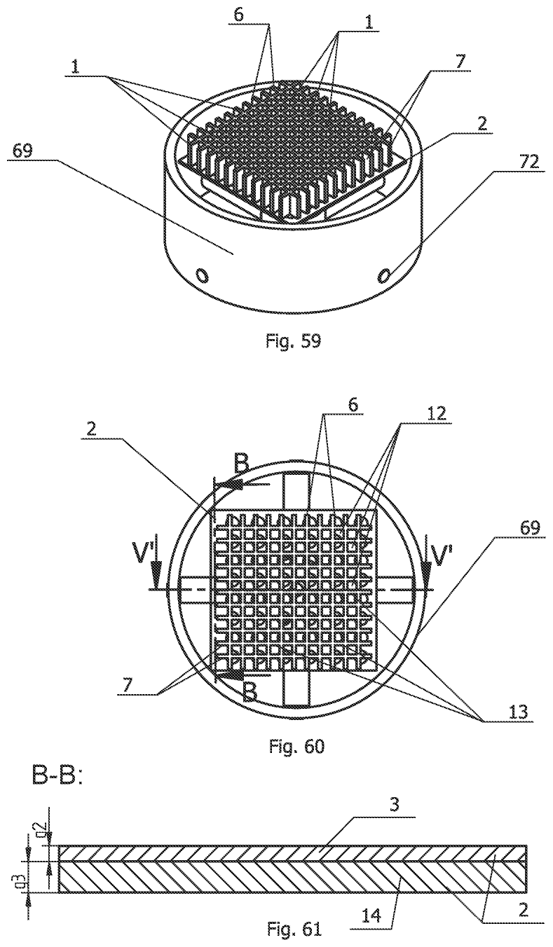

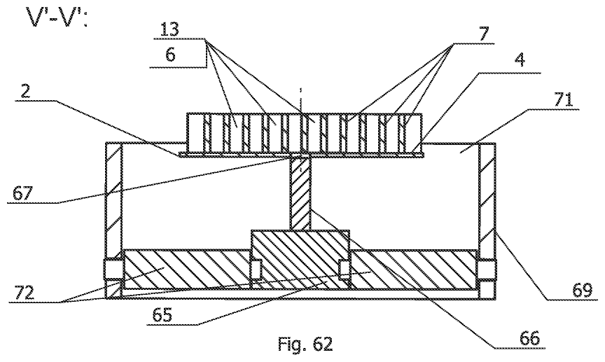

The subject of the invention in ten variants of its embodiment and in two variants of its improvement was presented in FIGS. 1-62, of which FIGS. 1-7 present the first variant of embodiment of the multilayer photovoltaic panel with a cuboidal lattice structure, whereas FIG. 1 shows the panel, in the perspective view; FIG. 2—the same panel with its components disassembled, in the perspective view; FIG. 3—one of the strip-shaped bearing or transverse photovoltaic modules with double-sided photovoltaic layers, constituting an element of the panel, in the front view; FIG. 4—the same bearing or transverse element of the panel in enlarged transverse section along line A-A; FIG. 5—perforated support plate of the panel with one-sided photovoltaic layer in enlarged transverse section along line B-B; FIG. 6—enlarged detail “C” of the panel, in the perspective view; and FIG. 7—enlarged detail “D” of the panel, in the perspective view. FIGS. 8-16 illustrate the second variant of embodiment of the panel according to the invention with an oblique parallelogram lattice structure, whereas FIG. 8 shows the panel in the perspective view; FIG. 9—the same panel with its components disassembled, in the perspective view; FIG. 10—one of the strip-shaped bearing photovoltaic modules with double-sided photovoltaic layers constituting an element of the panel, in the front view; FIG. 11—one of the strip-shaped transverse photovoltaic modules with double-sided photovoltaic layers constituting an element of the panel, in the front view; FIG. 12—a strip-shaped bearing and transverse element of the panel in transverse section along line E-E; FIG. 13—a strip-shaped bearing and transverse element of the panel in transverse section along line F-F; FIG. 14—perforated support plate with double-sided photovoltaic layer in vertical cross-section along line G-G; FIG. 15—enlarged detail “H” of the panel in the perspective view; and FIG. 16—enlarged detail “I” of the panel in the perspective view. FIGS. 17-23 illustrate the third variant of embodiment of the panel according to the invention with a lattice structure which, when seen from a side, has the profile of an overturned truncated pyramid, whereas FIG. 17 shows the panel in the perspective view; FIG. 18—the same panel with its components disassembled; FIG. 19—one of the strip-shaped bearing photovoltaic modules with double-sided photovoltaic layers constituting an element of the panel, in the front view; FIG. 20—one of the strip-shaped transverse photovoltaic modules with double-sided photovoltaic layers, constituting an element of the panel, in the front view; FIG. 21—a strip-shaped bearing and transverse element of the panel in transverse section along line J-J; FIG. 22—a strip-shaped and transverse element of the panel in enlarged transverse section along line K-K; and FIG. 23—enlarged detail “M” of the panel in the perspective view. FIGS. 24-30 show the fourth variant of embodiment of the panel according to the invention with a cylindrical lattice structure, whereas FIG. 24 shows the panel in the perspective view; FIG. 25—the same panel with its lattice subassembly and perforated support plate disassembled, in the perspective view; FIG. 26—on of cylindrical photovoltaic modules of the lattice subassembly with double-sided photovoltaic layer, in the perspective view; FIG. 27—the same cylindrical element, in the front view; FIG. 28—the same cylindrical element in horizontal section along line N-N; FIG. 29—enlarged detail “P” of the panel in the perspective view; and FIG. 30—enlarged detail “R” of the panel, in the perspective view. FIGS. 31-36 illustrate the fifth variant of embodiment of the panel according to the invention with triangular tubular lattice structure, whereas FIG. 31 shows the panel in the perspective view; FIG. 32—the same panel with its lattice subassembly and perforated support plate disassembled, in the perspective view; FIG. 33—one of the triangular tubular photovoltaic modules with double-sided photovoltaic layers constituting an element of the panel subassembly, in the perspective view; FIG. 34—the same photovoltaic module, in the top view; FIG. 35—the same photovoltaic module, in vertical cross-section along line U-U; and FIG. 36—enlarged detail “T” of the panel, in the perspective view. FIGS. 37 and 38 show the sixth variant of embodiment of the panel according to the invention representing a combination of the above-described fourth variant and the oblique lattice structure specific for the second variant of the panel, whereas FIG. 37 shows the panel in the perspective view, and FIG. 38—the same panel with its components disassembled, in the perspective view. FIGS. 39-43 depict the seventh variant of embodiment of the panel according to the invention with four cylindrical tubular photovoltaic modules with different diameters, arranged concentrically respective to each other, whereas FIG. 39 shows the panel in the perspective view; FIG. 40—a set of four cylindrical tubular photovoltaic modules of the panel in the top view; FIG. 41—the same set of photovoltaic modules in axial section along line X′-X′; FIG. 42—one photovoltaic module of the set of modules, in vertical cross-section along line X-X; and FIG. 43—enlarged detail A′ of the module in the perspective view. FIGS. 44-48 present the eight variant of embodiment of the panel according to the invention with four triangular tubular photovoltaic modules with different transverse dimensions of the modules, arranged concentrically respective to each other, whereas FIG. 44 shows the panel in the perspective view; FIG. 45—a set of four triangular tubular photovoltaic modules of the panel, in the top view; FIG. 46—the same set of photovoltaic modules, in vertical cross-section along line B′-B′; FIG. 47—a single photovoltaic module of the set of modules, in vertical cross-section along line C′-C′, and FIG. 48—enlarged detail E′ of the panel in the perspective view. FIGS. 49-51 show the ninth variant of embodiment of the panel according to the invention with photovoltaic modules with the structure of four triangles arranged concentrically respective to each other with their dimensions diminishing towards the centre of the structure disposed on photovoltaic module with the profile of the perforated support plate, whereas FIG. 49 shows the panel in the perspective view; FIG. 50—an isolated photovoltaic module with the structure of a triangular scroll with four coils, in the top view; and FIG. 51—photovoltaic module with double-sided photovoltaic layers in vertical cross-section along line Z-Z. FIGS. 52-54 illustrate the tenth variant of embodiment of the panel according to the invention with a photovoltaic module in the form of a scroll situated on a photovoltaic module with the profile of a perforated support plate, whereas FIG. 52 shows the panel in the perspective view; FIG. 53—an isolated photovoltaic module with the structure of a scroll, in the top view; and FIG. 54—a photovoltaic module with double-sided photovoltaic layers, in vertical cross-section along line W-W. FIGS. 55-58 show the eleventh variant of the panel according to the invention constituting the first variant of improvement of the first ten variants of the panel, said variant consisting in equipping these earlier variants in an electric motor driving a propeller and further equipping said earlier versions with a cylindrical tube, of which FIG. 55 shows the same improved multilayer photovoltaic panel in the perspective view; FIG. 56—the same panel in the top view; FIG. 57—the same panel in vertical cross-section along line W-W; and FIG. 58—the same panel in axial cross-section along line V-V. FIGS. 59-62 present the twelfth variant of the panel according to the invention constituting the second variant of improvement of the first ten variants of the panel, said variant consisting in equipping these earlier variants only in an electric motor setting the whole assembly of the panel in rotary motion and further equipping said earlier versions with a cylindrical tube in which said panel assembly is placed, of which FIG. 59 shows the same improved multilayer photovoltaic panel equipped additionally only in an electric motor and a cylindrical tube, in the perspective view; FIG. 60—the same panel in the top view; FIG. 61—the same panel in vertical cross-section along line B-B; and FIG. 62—the same panel in axial cross-section along line V′-V′.

### Example 1

The multilayer photovoltaic panel with increased solar radiation energy to electric energy conversion surface according to the first variant of its embodiment shown in FIGS. 1-7 comprises a lattice subassembly 1 and a support plate 2 with a perovskite photovoltaic layer 3 on its upper surface, connected inseparably, by means of a layer of an electrically conductive adhesive 4, with lower surfaces 5 of flat bearing strips of photovoltaic modules 6 and transverse strips of photovoltaic modules 7 of the subassembly, whereas the support plate 2 is provided with perforation 8 over the whole of its surface. In this example embodiment, the lattice subassembly 1 of the panel comprises eleven rectangular flat strip-shaped bearing photovoltaic modules 6 and eleven identical rectangular flat strips of transverse photovoltaic modules 7, all with length L, thickness g, and height h, with one of longer sides provided with slit-shaped recesses 9 with height h1 equaling a half of height h of these modules, i.e. h1=0.5 h, and width s adapted to thickness g. All the rectangular flat strip-shaped bearing photovoltaic modules 6 and strips of transverse photovoltaic modules 7 have inner plate-shaped stiffening elements 10 made of a transparent polymer plastic which in this case is polyethylene terephthalate (PET) with thickness g1=1200 nm both of the two outer surfaces of which are provided with perovskite photovoltaic layers 11 with thickness g2=200 nm. Eleven strip-shaped bearing photovoltaic modules 6 are situated parallel relative to each other so that their slit-shaped recesses 9 point upwards, and on said recesses, as well as on lower flat portions of surfaces of said modules, slit-shaped recesses 9 together with upper flat surfaces of the eleven strips of transverse photovoltaic modules 7 are fixed by means of the push-on method, as a result of which both upper and lower surfaces of all the these strip-shaped photovoltaic modules are flush with one another. Such arrangement of the modules connected with each other forms a lattice 12 over the whole surface of the support plate 2, said lattice being composed of identical cuboidal pockets 13 with square bases and heights h equaling the heights of bearing strips 6 and transverse strips 7. On the other hand, the support plate 2 comprises a plate-shaped stiffening element 14 made of a transparent plastic which in this case is polyethylene terephthalate (PET) with thickness g3=1 mm, upper surface of which is provided with a photovoltaic layer 3 with thickness g2=200 nm, and as a result of joining the layer, by means of electrically conductive adhesive 4, with lower surface of the lattice subassembly 1, plate-shaped photovoltaic modules of which are connected with each other by means of the push-on method, a single electric circuit has been set up composed of all photovoltaic layers 11 and 3, and the current generated as a result of conversion the solar radiation energy into electric energy is transmitted through electric conductors 15.

### Example 2

The multilayer photovoltaic panel with increased solar radiation energy to electric energy conversion surface according to the second variant of its embodiment shown in FIGS. 8-16 comprises a lattice subassembly 16 and a support plate 17 with double-sided perovskite photovoltaic layers 11, of which the upper layer is connected permanently, by means of an electrically conductive adhesive 4, with lower surfaces 5 of flat strip-shaped bearing photovoltaic modules 18 of the subassembly, whereas the rectangular support plate 17 is provided with perforation 8 on the whole of its surface. The difference between the multilayer panel according to the first variant of its embodiment illustrated in FIGS. 1-7 and the multilayer panel according to the second variant of its embodiment shown in FIG. 8-16 consists only in that in the second variant, one of longer sides of each flat rectangular strip-shaped bearing photovoltaic module 18 is provided with evenly distributed slit-shaped recesses 19 with the profile of a rectangular trapezium and height h3 equaling a half of height h2 of the bearing strips and width s1 corresponding to thickness g, which are also oriented parallel to each other and at an acute angle, preferably 45°, relative to upper surface of their longer sides, while one of longer sides of each of the flat strips of transverse photovoltaic modules 20 is provided with rectangular slit-shaped recesses 21, also distributed evenly but with height h4 equaling ⅓ of height h2 of these strips and width s1 corresponding to thickness g of the modules, which are also arranged parallel relative to each other. Moreover, in the second variant of embodiment of the multilayer photovoltaic panel, the flat strip-shaped photovoltaic modules 18 and 20 forming the lattice subassembly 16 have the form of inner plate-shaped stiffening elements 10 made of polyethylene terephthalate (PET) with thickness g1=1200 nm both of the two outer surfaces of which are inseparably connected with photovoltaic layers 11, each with thickness g2=300 nm. Further, the support plate 17 constitutes a plate-shaped stiffening element 14 made of transparent plastic which in this case is polyethylene terephthalate (PET) with thickness g1=1200 nm, both of the two outer surfaces of which are inseparably connected with photovoltaic layers 11, each with thickness g2=300 nm. Therefore, in the second variant of embodiment of the photovoltaic panel, eleven strip-shaped bearing photovoltaic modules 18 are also arranged parallel relative to each other so that the oblique slit-shaped recesses 19 point upwards, and on said recesses, as well as on lower flat portions of surfaces of said modules, rectangular slit-shaped recesses 21 of eleven strips of transverse photovoltaic modules 20 are fixed by means of the push-on method, so that their upper flat portions stick out above upper ends of the eleven strip-like bearing photovoltaic modules 18. As a result of the push-on connection between the twenty two flat strip-shaped photovoltaic modules 18 and 20, the whole surface of the panel constitutes a lattice 22 of parallelogram pockets with upper slit-free portions of transverse photovoltaic modules 20 sticking out above the pockets and with lower slit-free portions of strip-shaped bearing photovoltaic modules 18 sticking out before the pockets. Also in this variant of embodiment of the panel according to the invention, the push-on connection of flat strip-shaped bearing photovoltaic modules 18 with flat strip-shaped transverse photovoltaic modules 20 and lower surfaces of these strip-shaped bearing photovoltaic modules 18 connected with the upper perovskite photovoltaic layer 11 by means of an electrically conductive adhesive 4 resulted in setting up a single electric circuit composed of perovskite photovoltaic layers 11, and the current generated as a result of conversion the solar radiation energy into electric energy is transmitted through electric conductors 15.

### Example 3

The multilayer photovoltaic panel with increased solar radiation energy to electric energy conversion surface according to the third variant of its embodiment shown in FIGS. 17-23 comprises a lattice subassembly 23 and a support plate 2, which again is a PET plate 14 with thickness g3=900 nm with perovskite photovoltaic layer 3 on its upper surface joined permanently by means of an electrically conductive adhesive 4 with lower surfaces 5 of flat strip-shaped bearing photovoltaic modules 24 of the subassembly, whereas the rectangular support plate 2 is provided with perforation 8 over the whole of its surface. In this variant of embodiment, flat rectangular bearing strips of photovoltaic modules 24 are provided with evenly distributed pairs of slit-shaped recesses 25 with the profile of a rectangular trapezium with width s2 and height h3 equaling a half of height h2 of theses strips, oriented at an acute angle β, preferably 75°, relative to surfaces of these longer sides which are separated from each other with trapezium profiles 26 and 27 with different widths of their uppers sides 28 and 29, while one longer side of each of the transverse strips of photovoltaic modules 30 is also provided with evenly distributed rectangular slit-shaped recesses 31 with height h4 equaling a half of height h2 of the module, whereas both of the two strip-shaped photovoltaic modules, 24 and 30, all with identical length L, height h2, and thickness g, have slit-shaped recesses with the same width s2 and are composed of plate-shaped stiffening elements 10 of polyethylene terephthalate (PET), each with thickness g=0.8 mm, both of the two surfaces of which are inseparably connected with perovskite photovoltaic layers 11, each with thickness g2=250 nm, while the support plate 2 is made also of the same polymer plastic (PET), has thickness g3=900 nm, and its photovoltaic layer has thickness g2=250 nm. In this third variant of embodiment of the photovoltaic panel, eleven strip-shaped bearing photovoltaic modules 24 are also arranged parallel relative to each other so that oblique pairs of their slit-shaped recesses 25 point upwards, and rectangular slit-shaped recesses 31 of the twelve strips of transverse photovoltaic modules 30 are fixed, also by means of the push-on method, in both of the two types of recesses coated with a layer of an electrically conductive adhesive 4 and on lower flat portions of the modules, so that their upper flat faces 32 sticking out above upper faces 33 of bearing strips 24 contact with each other thus forming, when seen from a side, the profile of overturned letter “V” (and an overall profile close to an accordion-like one). Lower flat sides 5 of bearing strips-shaped photovoltaic modules 24 of the thus formed lattice subassembly 23 are connected, by means of an electrically conductive adhesive 4, with the support plate 2. As a result of the push-on connection between the twenty three flat strip-shaped photovoltaic modules 24 and 30, the whole surface of the panel constitutes a lattice of parallelogram pockets with upper ends and touching faces of strip-shaped transverse photovoltaic modules 30 sticking out above upper faces of the strip-shaped bearing photovoltaic modules 24. Such functional interconnection of all component elements of the panel according to this variant of embodiment of the invention resulted in setting up a single electric circuit composed of photovoltaic layers 11 and 3, and the current generated as a result of conversion the solar radiation energy into electric energy is transmitted through electric conductors 15.

### Example 4

The multilayer photovoltaic panel with increased solar radiation energy to electric energy conversion surface according to the fourth variant of its embodiment shown in FIGS. 24-30 comprises a lattice subassembly 34 and a support plate 2 with perovskite photovoltaic layer 3 provided on its upper surface connected permanently, by means of an electrically conductive adhesive 4, with lower tubular surfaces 5 of circular tubular photovoltaic modules 35 of the subassembly, whereas the rectangular support plate 2 is provided with perforation 8 over the whole of its surface. In this variant of embodiment, the lattice subassembly 34 is composed of thirty six three-layer identical circular tubular photovoltaic modules 35 arranged in six rows of six modules per row, where the first modules of every second row are advanced by a half of their diameter, and at their contact points, they are connected with each other by means of an electrically conductive adhesive 4. All the tubular photovoltaic modules 35 have the same thickness g, height h3, and inner diameter ϕ and have the form of inner tubular stiffening elements 36, each with thickness g1=0.5 mm, made of polyethylene terephthalate (PET), both surfaces of which, the inner and the outer, are provided with perovskite photovoltaic layers 11 with thickness g2=250 nm each joined inseparably with said surfaces, whereas the support plate 2, connected inseparably with said surfaces by means of an electrically conductive adhesive 4, is made also of the same polymer plastic with thickness g1=0.5 mm and is connected inseparably with a perovskite photovoltaic layer 3 with thickness g2=250 nm. As a result of all the photovoltaic layers of tubular photovoltaic modules 35 being connected with the photovoltaic layer 3 of the support plate 2 both by means of butt contacts and with the use of an conductive adhesive, a lattice with tubular pockets 37 and pockets 38 with the profile of isosceles triangles with concave sides was formed on the whole surface of said support plate. Such functional interconnection of all component elements of the panel according to this variant of embodiment of the invention resulted in setting up a single electric circuit composed of photovoltaic layers 11 and 3, and the current generated as a result of conversion the solar radiation energy into electric energy is transmitted through electric conductors 15.

### Example 5

The multilayer photovoltaic panel with increased solar radiation energy to electric energy conversion surface according to the fifth variant of its embodiment shown in FIGS. 31-36 comprises a lattice subassembly 39 and a support plate 17 connected permanently, by means of an electrically conductive adhesive 4, with lower surfaces of photovoltaic modules 40 with the profile of triangular tubes. The lattice subassembly 39 of the multilayer panel is composed of identical photovoltaic modules 40 with the profile of triangular tubes, all with identical height h4, thickness g, and width s3 of their side walls, arranged vertically in rows and with their side walls connected with each other by means of an electrically conductive adhesive 4, whereas all the photovoltaic modules 40 and the support plate 17 connecting them have the same thickness g. Photovoltaic modules 40 constitute identical inner stiffening elements 41 with thickness g1=900 nm with the profile of triangular tubes made of polyethylene terephthalate (PET), both surfaces of which, the inner and the outer, are provided with perovskite photovoltaic layers 11 with thickness g2=200 nm each inseparably connected with said surfaces. Also in this variant of embodiment of the multilayer panel, by connecting all the photovoltaic modules 40 making up the lattice subassembly 39 by means of layers of an electrically conductive adhesive 4 and connecting the base of the subassembly with upper photovoltaic layer 11 of the support plate 17 by means of the same adhesive it was possible to form a lattice 42 with pockets 43 with the profile of triangles. Such functional interconnection of all component elements of the panel according to this variant of embodiment of the invention resulted in setting up a single electric circuit composed of all these perovskite photovoltaic layers 11, and the current generated as a result of conversion the solar radiation energy into electric energy is transmitted through electric conductors 15.

### Example 6

The multilayer photovoltaic panel with increased solar radiation energy to electric energy conversion surface according to the sixth variant of its embodiment illustrated in FIGS. 37-38 represents a combination of the photovoltaic panel according to the fourth variant of its embodiment illustrated in FIGS. 24-30 and the lattice subassembly 16 making up the photovoltaic panel according to the second of its variants shown in FIGS. 8-16, whereas the combination consists in that lower face walls 5 of rectangular flat plate-shaped photovoltaic modules 18 constituting elements of the lattice subassembly 16 of the panel are fixed permanently, by means of layers of an electrically conductive adhesive 4, to upper face surfaces of circular tubular photovoltaic modules 35 resulting in formation of a lattice with tubular pockets 37 and parallelogram pockets 22. As a result of such connection, the number of photovoltaic modules was increased with significantly increased surface of perovskite photovoltaic layers 11 resulting in increased quantity of solar radiation energy converted into electric energy transmitted through electric conductors 15.

### Example 7

The multilayer photovoltaic panel with increased solar radiation energy to electric energy conversion surface according to the seventh variant of its embodiment shown in FIGS. 39-43 is composed of a support plate 2 with its surface provided with perforation 8 and a chamber subassembly 44 composed of four concentrically arranged cylindrical photovoltaic modules 45, all with identical height lower faces 46 of which, by means of an electrically conductive adhesive 4, are connected with upper perovskite photovoltaic layer 3 of the support plate so that the modules are separated from each other with cylindrical chambers 47. The support plate 2 with rectangular profile is made of polyethylene terephthalate (PET) and has thickness g1=1 mm, while its upper surface is coated permanently with perovskite photovoltaic layer 3 with thickness g2=200 nm, while the tubular photovoltaic modules 45 connected with the support plate are composed of inner tubular stiffening elements 48 with thickness g1=1 mm each made of polyethylene terephthalate (PET), with both outer surface of the elements joined inseparably with z perovskite photovoltaic layers 11, each with thickness g2=200 nm, whereas the diameter of the largest outermost cylindrical photovoltaic module 45 is ϕ2=20 cm, while chambers 47 formed between the modules have width s4=5 mm each. The use of several cylindrical photovoltaic modules 45 arranged concentrically relative to each other, provided with double-sided perovskite photovoltaic layers 11, and separated from each other with cylindrical chambers 47, as well as connection of lower faces 46 of the modules with perovskite photovoltaic layer 3 of the support plate 2 allows also to obtain a significant increase of surface area exposed to solar radiation converted to electric energy which is transmitted through electric conductors 15.

### Example 8

The multilayer photovoltaic panel with increased solar radiation energy to electric energy conversion surface according to the eight variant of its embodiment shown in FIGS. 44-48 is composed of rectangular support plate 2 provided with perforation 8 on its surface and a chamber subassembly 49 which is formed by four triangular photovoltaic modules 50 arranged concentrically respective to each other and separated from each other with four triangular chambers 51. Lower faces 52 of the modules are connected, by means of an electrically conductive adhesive 4, with upper perovskite photovoltaic layer 3 of the support plate. This support plate with rectangular profile is made of polyethylene terephthalate (PET) with thickness g1=0.75 mm, and its upper surface connected with lower faces 52 of the photovoltaic modules 50 is coated permanently with photovoltaic layer 3 with thickness g2=250 nm, while modules 50 are composes as plate-shaped inner stiffening elements 53 with thickness g1=0.75 mm each made polyethylene terephthalate (PET) both outer surfaces of which being joined permanently with perovskite photovoltaic layers 11 with thickness g2=250 nm each, whereas peripheral triangular chambers 51 formed between said modules have width s5=3 mm each, and sides of the largest outermost photovoltaic module 50 have width s6=25 cm each. The use of several tubular photovoltaic modules 50 arranged in a mutually concentric way, provided with double-sided photovoltaic layers 11, separated from each other with triangular chambers 51 with their lower faces 52 connected with the upper photovoltaic layer 3 of the support plate 2 enables to obtain an increase of surface area exposed to solar radiation converted to electric energy transmitted through electric conductors 15.

### Example 9

The multilayer photovoltaic panel with increased solar radiation energy to electric energy conversion surface according to the ninth variant of its embodiment illustrated in FIGS. 49-51 comprises a rectangular support plate 2 with perforation 8 provided on its surface and a chamber subassembly 54′ which has the form of a monolithic photovoltaic module 54, composed of an inner stiffening element 55 with thickness g1=0.5 mm made of polyethylene terephthalate (PET) with both surfaces coated with perovskite photovoltaic layers 11, each with thickness g2=300 nm, whereas the photovoltaic module 54 has the profile of a triangular scroll with triangular coils, each or such profiles having thus an open outer end 56 and an open inner end 57, whereas inside each of the thus coiled triangular profiles, a continuous chamber 58 with analogous profile is formed. Lower ends 59 of the thus formed photovoltaic module 54 are connected permanently, by means of a layer of an electrically conductive adhesive 4, with the perovskite photovoltaic layer 3 of the support plate 2 with structure identical to this of the photovoltaic module.

By using a uniform photovoltaic module 54 with large developed surface but scrolled in the form of triangles arranged concentrically relative to each other and provided with double-sided perovskite photovoltaic layers 11 separated from each other with chambers 58 with width s7=4 mm and connecting the lower end of the profiled module with upper perovskite photovoltaic layer 3 of the support plate 2, it was possible also to obtain an increase of the surface area exposed to solar radiation converted to electric energy transmitted through electric conductors 15.

### Example 10

The multilayer photovoltaic panel with increased solar radiation energy to electric energy conversion surface according to the tenth variant of its embodiment shown in FIGS. 52-54 comprises a rectangular support plate 17 with perforation 8 on its surface and a chamber subassembly 60′ which has the form of a monolithic chamber-like photovoltaic module 60 composed of an inner stiffening element 61 made of polyethylene terephthalate (PET) with thickness g1=0.75 mm having the profile of a scroll with both surfaces coated with perovskite photovoltaic layers 11 with thickness g2=250 nm each, while width of the chamber 62 formed between subsequent coils of the scroll is s8=5 mm. Lower end 63 of the thus formed photovoltaic module 60 is connected permanently, by means of a layer of an electrically conductive adhesive 4, with the upper perovskite photovoltaic layer 11 of the support plate 17.

By using the monolithic chamber-like photovoltaic module 60 coiled to form the profile of a scroll with chamber 62 formed between coils of the scroll and connecting the lower end of such profiled module with upper perovskite photovoltaic layer 11 of the support plate 17 it also became possible to obtain an increase of surface area exposed to solar radiation converted to electric energy transmitted through electric conductors 15.

In further example embodiments of the multilayer photovoltaic panel according to the invention, in all the photovoltaic modules and in all the support plates, stiffening elements made of isolated graphene were employed instead of stiffening elements 10, 14, 41, 48, 53, 55 of polyethylene terephthalate (PET), whereas the photovoltaic layers 3 or 11 were the dye-sensitised solar cells (DSSCs), quantum dot (QD) cells, or organic photovoltaic (OPV) cells. Moreover, in another example embodiments of the photovoltaic panels (not shown in drawings) photovoltaic modules 44 or 49 as well as 54 or 60 were replaced with photovoltaic modules transverse cross-sections of which have the shape of polygons, including squares and hexagons. It is understood that depending on overall dimensions of support plates 2 and 17, the number of photovoltaic modules 6 and 7 or 18 and 20 or 24 and 30, as well as photovoltaic modules 35 or 40, is adapted to dimensions of the support plates in order to cover the whole of their surfaces. Also the number of photovoltaic modules 45 or 50 and chamber subassemblies 44 or 49 is adapted to dimensions of support plates 2 or 17; moreover the chamber subassemblies 44 or 49 as well as the photovoltaic modules 54 and 60 may be connected with each other by means of electrically conductive adhesive 4 and connected by means of said adhesive with photovoltaic layer 3 or 11 of a single support plate 2 or 17 sequentially relative to each other in a way described, for instance, in Examples 4 and 5.

### Example 11

The multilayer photovoltaic panel with increased solar radiation energy to electric energy conversion surface according to the eleventh improved variant of its embodiment shown in FIGS. 55-58, comprises a square support plate 17 with perforation 8 on its surface and a chamber subassembly 60′ which constitutes a monolithic chamber-like photovoltaic module 60 composed of an inner stiffening element 61 having the profile of circular scroll made of polyethylene terephthalate (PET) with thickness of g1=0.75 mm, both surfaces of which are coated with perovskite photovoltaic layers 11 with thickness g2=250 nm, and the width of the chamber 62 formed between successive coils of the scroll is s8=5 mm. The lower end 63 of scroll-shaped photovoltaic module 60 situated as described above, is joined permanently, with the use of a glue 4 capable to conduct electric, with the upper perovskite photovoltaic layer 11 of the support plate 17. Moreover, additionally, an electric motor 65 is placed in an axial bore 64 of the scroll-shaped photovoltaic module 60, said motor being adjacent to and joined with to the perovskite support plate 17 and to the scroll-shaped module, and a drive shaft 66 of the motor is mounted with a clearance in an axial hole 67 of the support plate, whereas the lower end of the shaft is provided with a propeller 68 setting in rotary motion by the electric motor, whereas the lower portion of the multilayer photovoltaic panel constructed as described above is placed in upper portion of a cylindrical tube 69 fixed, by means of screws, 70, to outer whorl of the scroll-shaped photovoltaic module 60 so that between the inner surface of the cylindrical tube 69 and side walls of the support plate 17, a circumferential slit 71 is formed allowing appearance of the stack effect and thus obtaining an additional draught of air cooling the chamber subassembly 60′ of the photovoltaic panel.

### Example 12

The multilayer photovoltaic panel with increased solar radiation energy to electric energy conversion surface according to twelfth variant of its embodiment shown in FIGS. 59-62, comprises a lattice subassembly 1 composed of vertically oriented flat bearing strips of photovoltaic modules 6 joined with perpendicularly oriented identical strips of photovoltaic modules 7, forming thus pockets 13 with square bases between them, whereas the strips of both of the modules 6 and 7 have plate-shaped stiffening elements 10 made of polyethylene terephthalate (PET) both surfaces of which are coated with perovskite photovoltaic layers 11 (as shown in FIG. 4 of the patent application No. 425998). The strip-shaped photovoltaic modules 6 and 7 joined with each other that way, are at the same time joined, with the use of an adhesive 4, with a perforated support plate 2 provided on its upper surface with a perovskite photovoltaic layer 3. Moreover, upper end of a drive shaft 66 of an electric motor 65 situated in the symmetry axis of the lattice subassembly 1 of the panel is fixed to the support plate 2, whereas the motor is joined with lower end of a cylindrical tube 69 by means of four supporting bar-shaped elements 72 oriented horizontally and perpendicularly to each other, so that the lower portion of the whole structure of the multilayer photovoltaic panel, i.e. the support plate 2 and lower portion of the lattice subassembly 1 are placed in upper portion of said cylindrical tube forming thus a circumferential slit between side walls of the plate and inner surface of the cylindrical tube 69.

Similar combination of an electric motor 65, drive shaft 66 of which is equipped with propeller 68, with the perovskite support plate 2 or 17, and positioning lower portions of structures of multilayer photovoltaic panels in cylindrical tubes 69, joined by means of screws 70 with lattice subassemblies 1, 16, 23, 34, and 39 or chamber subassemblies 44, 49, and 54′, was employed in other variants of embodiment of the photovoltaic panel described in Examples 1-9 of the patent application No. P.425998, achieving thus the analogous cooling effect in each of the variants.

Also similar combination of the drive shaft 66 of the electric motor 65 with the perovskite support plate 2 or 17, positioning lower portions of structures multilayer photovoltaic panels in a cylindrical tube 69 and joining said lower portions, by means of four supporting bar-shaped elements 72, with lower end of said cylindrical tube, was employed in other variants of embodiment of the photovoltaic panel described in embodiment Examples 2-10 of the patent application No. P. 425998, achieving the analogous effect in each of the variants.

All the improved variants of embodiment of the multilayer photovoltaic panel equipped additionally with an electric motor 65 equipped with an electric battery (not shown in drawings), setting in rotary motion a propeller 68 or setting in rotary motion the photovoltaic panel, and further equipped with cylindrical tube 69 joined detachably with the panel, said components being equipped with a temperature sensor (also not shown in drawings), co-operate with a typical remote wireless system (again not shown in drawings) controlling both switching the electric motor on and off and lifting and maneuvering the photovoltaic panel in the air, using for this purpose a remote wireless communication system comprising a remote control device equipped with a program and a PC-class computer.

Moreover, in further example embodiments of multilayer photovoltaic panels, support plates 2 and 17 of the panels were equipped in two and four, respectively, electric motors 65 provided with propellers 68, said motors being distributed symmetrically respective to each other, i.e. in corners of and fixed to the support plates.

1. A multilayer photovoltaic panel with increased solar radiation energy to electric energy conversion surface in which elements converting the energy are constructed based on photovoltaic modules, the photovoltaic modules comprising:
a lattice subassembly (1, 16, 23, 34, or 39) or at least one the chamber subassembly (44, 49, 54′, or 60′),
wherein the component photovoltaic modules (6 and 7) or (18 and 20) or (24 and 30) or (35) or (40) or (45) or (50) or (54) or (60) are connected inseparably with a photovoltaic layer (3) or (11) of a perforated support plate (2) or (17).

2. The multilayer panel according to claim 1, wherein the perforated support plate (2) is a plate-shaped stiffening element (14) provided with the photovoltaic layer (3).

3. The multilayer panel according to claim 1, wherein the perforated support plate (17) is a plate-shaped stiffening element (14), both of the two surfaces of which are provided with photovoltaic layers (11).

4. The multilayer panel according to claim 1, wherein the lattice subassembly (1) comprises rectangular strip-shaped bearing photovoltaic modules (6) and analogous flat transverse photovoltaic modules (7), composed of plate-shaped stiffening elements (10) both of the two outer surfaces of which are provided with photovoltaic layers (11), whereas the photovoltaic modules (6 and 7) are arranged perpendicularly relative to each other and connected with each other by a push-on method with the use of slit-shaped recesses (9) provided on their longer upper sides, so that both lower and upper surfaces of these strip-shaped photovoltaic modules (6 and 7) are flush with one another, while the slit-shaped recesses (9) of both of the two types of the modules have width (s) adapted to thickness (g) of these strip-shaped modules.

5. The multilayer panel according to claim 1, wherein it's the lattice subassembly (16) comprises flat strip-shaped bearing photovoltaic modules (18) arranged parallel relative to each other longer upper sides of which are provided with slit-shaped recesses (19) oriented at an acute angle (α) relative to their upper surfaces, and further comprises strip-shaped transverse photovoltaic modules (20) with slit-shaped recesses (21) perpendicularly arranged in their lower longer sides, whereas the photovoltaic modules (18) and (20) are composed of plate-shaped stiffening elements (10) both of the two outer surfaces of which are provided with photovoltaic layers (11) and moreover, both of the two types of modules are connected with each other by means of the push-on method with the use of slit-shaped recesses (19 and 21) so that upper ends of the photovoltaic modules (20) stick out above upper surfaces of the photovoltaic modules (18).

6. The multilayer panel according to claim 1, wherein the lattice subassembly (23) comprises flat strip-shaped bearing photovoltaic modules (24) arranged parallel relative to each other with their longer upper sides with evenly distributed pairs of slit-shaped recesses (25) oriented at acute angles (β) relative to their upper surfaces, and further comprises strip-shaped transverse photovoltaic modules (30) also arranged parallel relative to each other with slit-shaped recesses (31) arranged perpendicularly relative to their lower longer sides, whereas the photovoltaic modules (24) and (30) are composed of plate-shaped stiffening elements (10) both of the two outer surfaces of which are provided with photovoltaic layers (11), and moreover, the two types of the modules are connected with each other by means of the push-on method so that the upper ends of transverse photovoltaic modules (30) are oriented obliquely relative to each other and stick out above surfaces of upper sides of the photovoltaic modules (24).

7. The multilayer panel according to claim 1, wherein the lattice subassembly (34) comprises circular tubular photovoltaic modules (35) arranged vertically side by side in rows so that the first modules of each second row are advanced by a half of their diameters, whereas the modules are connected with each other at their contact points by means of an electrically conductive adhesive (4) forming thus a single monolithic subassembly, and moreover, all the tubular photovoltaic modules (35) have the form of tubular stiffening elements (36) both of the two outer surfaces of which are provided with photovoltaic layers (11).

8. The multilayer panel according to claim 1, wherein the lattice subassembly (39) comprises photovoltaic modules (40) with the profile of triangular tubes arranged vertically in rows and having their side walls connected with each other by means of a layer of an electrically conductive adhesive (4), said modules having the form of stiffening elements (41) both of the two outer surfaces of which are provided with photovoltaic layers (11).

9. The multilayer panel according to claim 5, wherein lower face walls (5) of flat rectangular strip-shaped photovoltaic modules (18) constituting elements of the lattice subassembly (16) of the panel are fixed permanently, by means of layers of an electrically conductive adhesive (4), to upper face surfaces of circular tubular photovoltaic modules (35).

10. The multilayer panel according to claim 1, wherein the chamber subassembly (44) is composed of tubular photovoltaic modules (45) with different diameters and identical height, arranged concentrically relative to each other and having the form of a tubular stiffening element (48) both of the two outer surfaces of which are provided with photovoltaic layers (11), whereas cylindrical chambers (47) are formed between said modules.

11. The multilayer panel according to claim 1, wherein it's the chamber subassembly (49) is composed of triangular photovoltaic modules (50) with identical height arranged concentrically relative to each other and separated from each other with triangular chambers (51), each of said triangular modules being composed of plate-shaped stiffening elements (53) with both of the two outer surfaces provided with photovoltaic layers (11).

12. The multilayer panel according to claim 1, wherein the photovoltaic chamber subassembly (54′) has the form of an inner stiffening element (55), both of the two outer surfaces of which are provided with photovoltaic layers (11), said stiffening element being folded to form a triangular scroll with triangular coils situated concentrically relative to each other and having an open outer end (56) and an inner end (57), whereas between the coils of the thus folded scroll, a continuous chamber (58) is formed.

13. The multilayer panel according to claim 1, wherein the chamber subassembly (60′) has the form of an inner stiffening element (61) with the profile of a circular scroll both of the two outer surfaces of which are provided with photovoltaic layers (11) with a continuous chamber (62) formed between coils of the scroll.

14. The multilayer panel according to claim 13, wherein the stiffening elements (10, 14, 36,41, 48, 53, 55, 61) are made of polyethylene terephthalate (PET).

15. The multilayer panel according to claim 13, wherein the stiffening elements (10, 14, 36,41, 48, 53, 55, 61) are made of isolated graphene.

16. The multilayer panel according to claim 1, wherein the photovoltaic layers (3) or (11) are perovskite layers or DSSCs or QD cells or OPV cells.

17. The multilayer panel according to claim 1, wherein further including an electric motor mounted (65) in the vertical axis of symmetry of both the support plates (2 or 17) with one or two perovskite photovoltaic layer(s) (3 or 11) and lattice subassemblies (1, 16, 23, 34, or 39) or chamber subassemblies (44, 49, or 54) joined inseparably with said subassemblies, said electric motor being mounted in coaxial profiled sockets (13, 22′, 30′, 37, 43) formed in said subassemblies, or in a coaxial inner cylindrical photovoltaic module (45), or in a coaxial inner triangular chamber (51 or 58) or in a coaxial hole (64) of a scroll-shaped chamber subassembly (60′), by joining said motor detachably with said sockets, or with this cylindrical photovoltaic module (45), or with the inner triangular chamber, or with an axial hole of the scroll-shaped chamber subassembly and with these support plates (2 or 17) with perforations (8) so that a drive shaft (66) of the motor (65) is mounted with a clearance with an axial hole (67) of the support plate (2 or 17), and the lower end of the shaft is provided with a propeller (68) set in rotary motion by the motor, whereas the whole structure of each of said multilayer photovoltaic panels is placed in a cylindrical tube (69) joined detachably with the corresponding lattice subassembly (1, 16, 23, 34, or 39) or the chamber assembly (44, 49, 54′, or 60′) so that a circumferential slit (71) is formed between the inner surface of the cylindrical tube (69) and side walls of the support plate (2 or 17).

18. The multilayer panel according to claim 17, wherein the support plates (2 or 17) are equipped with several electric motors (65) attached to said plates, distributed symmetrically on said plates and with respect to each other, and equipped with propellers (68).

19. The multilayer panel according to claim 16, wherein the upper end of a drive shaft (66) of an electric motor (65) is fixed to the support plates (2 or 17) in their symmetry axes and to lattice subassemblies (1, 16, 23, 34, or 39) or chamber subassemblies (44, 49, 54′, or 60′) joined inseparably with said support plates, said motor setting in rotary motion the assembly composed of the support plate (2 or 17) and the corresponding lattice assembly or chamber assembly, whereas said motor, by means of several supporting rod-shaped elements (72) situated horizontally symmetrically with respect to each other, is joined with lower end of a cylindrical tube (69) so that the lower portion of the panel is placed in upper portion of the cylindrical tube (69) forming thus a circumferential slit (71) between inner surface of the tube and side walls of the support plate (2 or 17).
